(19) United States
(12) Patent Application Publication
(10) Pub. No.: US 2004/0262701 A1
(43) Pub. Date: Dec. 30, 2004

(54) Nitridation process for independent control of device gate leakage and drive current

(75) Inventors: Husam N. Alshareef, Murphy, TX (US); Hiroaki Niimi, Dallas, TX (US); Rajesh Khamankar, Coppell, TX (US); Ajith Varghese, McKinney, TX (US)

Correspondence Address: TEXAS INSTRUMENTS INCORPORATED, P O BOX 655474, M/S 3999, DALLAS, TX, 75265

(73) Assignee: Texas Instruments Incorporated, Dallas, TX (US)

(21) Appl. No.: 10/824,862

(22) Filed: Apr. 15, 2004

Related U.S. Application Data
(60) Provisional application No. 60/480,866, filed on Jun. 24, 2003.

(51) Int. Cl. H01L 29/76; H01L 29/94

(52) U.S. Cl. 257/410

(57) ABSTRACT

The present invention provides a method for controlling the gate leakage in a semiconductor device. In one aspect, the method includes placing a semiconductor substrate in a plasma chamber and subjecting a gate dielectric layer located over the semiconductor substrate to a gas mixture including argon and nitrogen under plasma conditions, wherein a gas flow rate of the argon ranges from about 1700 sccm to about 2200 sccm and a flow rate of the nitrogen ranges from about 40 sccm to about 200 sccm.

### CROSS-REFERENCE TO PROVISIONAL APPLICATION

This application claims the benefit of U.S. Provisional Application No. 60/480,866 entitled “NITRIDATION PROCESS FOR INDEPENDENT CONTROL OF DEVICE GATE LEAKAGE CURRENT AND DRIVE CURRENT,” to Alshareef Husam, et al., filed on Jun. 24, 2003, which is commonly assigned with the present invention and incorporated herein by reference as if reproduced herein in its entirety.

### TECHNICAL FIELD OF THE INVENTION

The present invention is directed, in general, to a method for manufacturing a semiconductor device, and, more specifically, to a method for controlling device gate leakage without sacrificing device performance.

### BACKGROUND OF THE INVENTION

High performance integrated circuits have gained wide acceptance and utility in present day telecommunications devices that utilize high data applications. In addition, however, there is a great demand for shrinking these semiconductor devices to provide an increased device density on the semiconductor chip and provide chips that are faster, but at the same time, consume less power to conserve and extend battery life. In fact, to provide the required device performance, the scaling of the gate dielectric thickness in these devices has now reached below 2.0 nm.

However, simply scaling standard dielectrics while maintaining good process control in this thickness regime is very difficult. Thus, the industry is left with the desire to use thicker films that are correspondingly easier to control to tight limits, while decreasing the electrical dielectric thickness to increase device performance (increase drive current or I_{DS}) with less leakage and without degradation to long channel threshold voltages.

To achieve these goals, the industry has turned to the use of higher dielectric constant materials. One such material that has found popular utility is a plasma nitridated oxide or PNO. In a typical nitridation process, a low pressure, radio frequency (RF) nitrogen plasma or other known method for nitridation is used to implant a dielectric with uniformly high doses of nitrogen. The addition of this nitrogen effectively increases the dielectric constant value of the gate dielectric, thus allowing a physically thicker film to be electrically thinner. In other words, a smaller equivalent oxide thickness (EOT) is achieved. The presence of the nitride in the gate oxide also blocks boron penetration, which prevents the boron from getting into the channel region, which could further affect device performance.

As the semiconductor industry continues to improve its process technologies, controlling or reducing the amount of leakage associated with these transistors becomes increasingly difficult. Further, the amount of leakage associated with a transistor during its use has experienced a growing concern within the semiconductor industry. Concern over this issue has increased as the desire to extend the battery life used in telecommunication devices has also become of greater importance.

Thus, while the increase of the nitrogen in the gate oxide allows smaller EOTs to be achieved, the amount of leakage from the gate oxide increases as EOT decreases, which is undesirable in high performance data application devices where power conservation is becoming ever increasingly important.

Accordingly, what is needed in the art is a method of manufacturing an integrated circuit that provides a reduction in the gate leakage of the device by incorporating nitrogen in the film without sacrificing device performance.

### SUMMARY OF THE INVENTION

To address the above-discussed deficiencies of the prior art, the present invention provides a method for controlling the gate leakage in a semiconductor device. In one embodiment, the method includes placing a semiconductor substrate in a plasma chamber and subjecting a gate dielectric layer located over the semiconductor substrate to a gas mixture including argon and nitrogen under plasma conditions, wherein a gas flow rate of the argon ranges from about 1700 sccm to about 2200 sccm and a flow rate of the nitrogen ranges from about 40 sccm to about 200 sccm.

Another embodiment of the present invention includes a method of forming a gate dielectric in a microwave plasma chamber. This particular embodiment includes placing a semiconductor substrate in a microwave plasma chamber, forming a gate dielectric layer over the semiconductor substrate, and subjecting the gate dielectric within the microwave plasma chamber to a gas mixture including argon and nitrogen under plasma conditions, wherein a gas flow rate of the argon ranges from about 1700 sccm to about 2200 sccm and a flow rate of the nitrogen ranges from about 40 sccm to about 200 sccm and under high pressure.

In yet another embodiment, the present invention provides a semiconductor device having a predetermined gate leakage. This embodiment comprises a semiconductor substrate and a gate dielectric layer located over the semiconductor substrate. The gate dielectric layer has a concentration of nitrogen therein that ranges from about 5% to about 15% and an equivalent oxide thickness that ranges from about 1.0 nm to about 1.5 nm and wherein a gate leakage of the gate dielectric layer is less than about 100 A/cm².

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they could readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following detailed description taken in conjunction with the accompanying FIGURES. It is emphasized that various features may not be drawn to scale. In fact, the dimensions of various features may be arbitrarily increased or reduced for clarity of discussion. In addition, it is emphasized that some circuit components may not be illustrated for clarity of discussion. Reference is now made to the following descriptions taken in conjunction with the accompanying drawings, in which:

FIG. 1 illustrate representative graph lines of EOT vs. J_{g} of conventional devices in contrast to a device made in accordance with the principles of the present invention;

FIG. 2A illustrates sectional view of the device of FIG. 1 after formation of the dielectric layer but prior to being subjected to a nitridation process;

FIG. 2A illustrates sectional view of the device of FIG. 1 following the formation of a gate dielectric layer as it is being subjected to a nitridation process;

FIG. 3 is a graph showing a relationship between a percentage of nitrogen concentration, gate leakage, and EOT of devices provide by the present invention and device fabricated using conventional processes;

FIG. 4 illustrates a sectional view of the device shown in FIG. 2 after the conventional formation of dual gates; and

FIG. 5 illustrates a partial view of a dual voltage integrated circuit device that can be fabricated in accordance with the principles of the present invention.

### DETAILED DESCRIPTION

The present invention uniquely recognizes that gate leakage can be controlled within a nitridation plasma process without sacrificing EOT and gate performance. It has presently been found that, contrary to conventional practice, that a relatively high nitrogen concentration within a gate dielectric layer can be achieved while decreasing the amount of gate leakage within a device without degrading device performance.

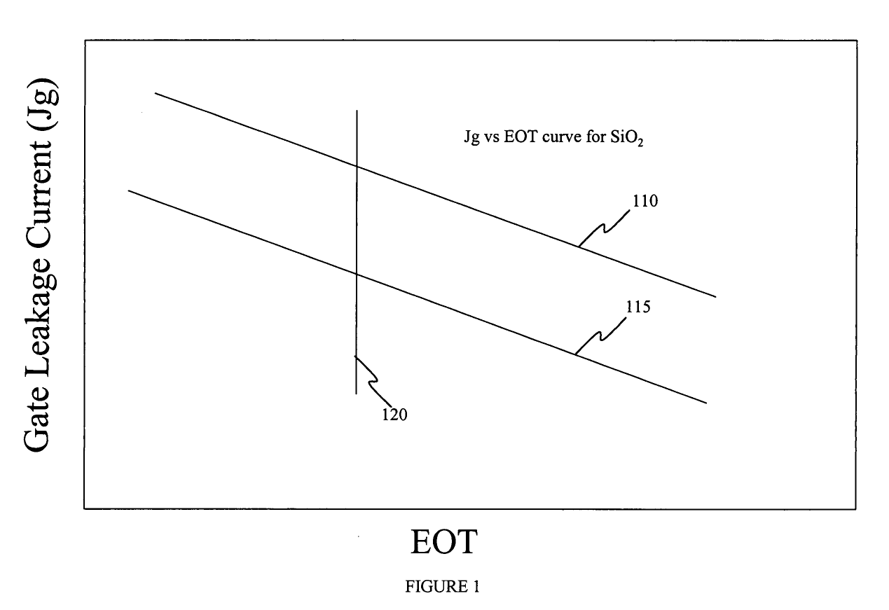

Turning initially to FIG. 1, there is illustrated a graph that plots EOT versus gate leakage current (J_{g}). Line 110 is a representative graph of the EOT/J_{g} relationship of a device when not subjected to nitridation, and line 115 is a representative graph of the EOT/J_{g} relationship of a device when subjected to a conventional nitridation process. In contrast, line 120 is a representative graph of the EOT/J_{g} of a device when subjected to a nitridation process as provided by one embodiment of the present invention. As seen from line 120, by varying the nitrogen content in accordance with the principles of the present invention, leakage current can be reduced at a fixed performance (i.e., a fixed EOT) . This is in contrast to conventional process, as demonstrated by lines 110 and 115, that either sacrifices gate leakage in favor of a given performance or sacrifices performance in favor of a given gate leakage.

Thus, for the first time, the present invention provides a method for tailoring the gate leakage at a fixed performance or tailoring a fixed performance at a given gate leakage for a given application. For example, as discussed above, many high data performance applications in present telecommunication technologies have a battery has a power source. In such applications, the gate dielectrics could be manufactured using the present invention. This would minimize gate leakage and conserve battery power, while at the same time, providing a gate dielectric having the targeted EOT and desired device performance.

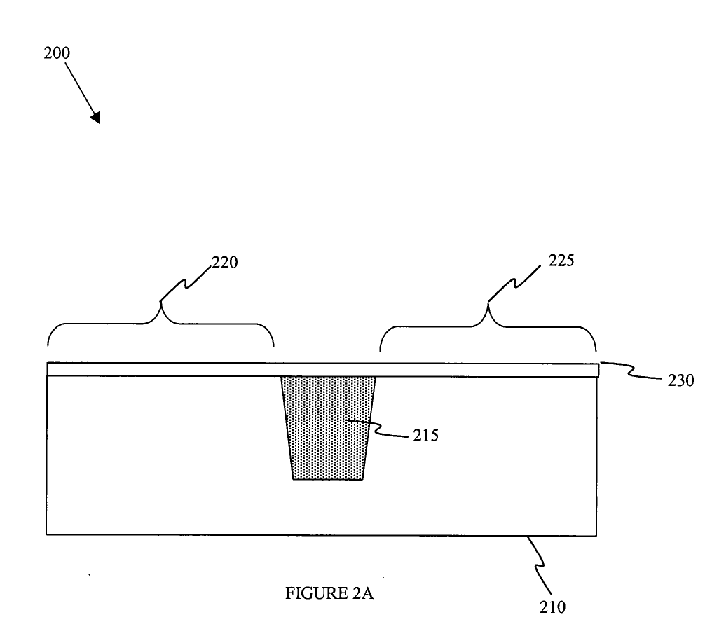

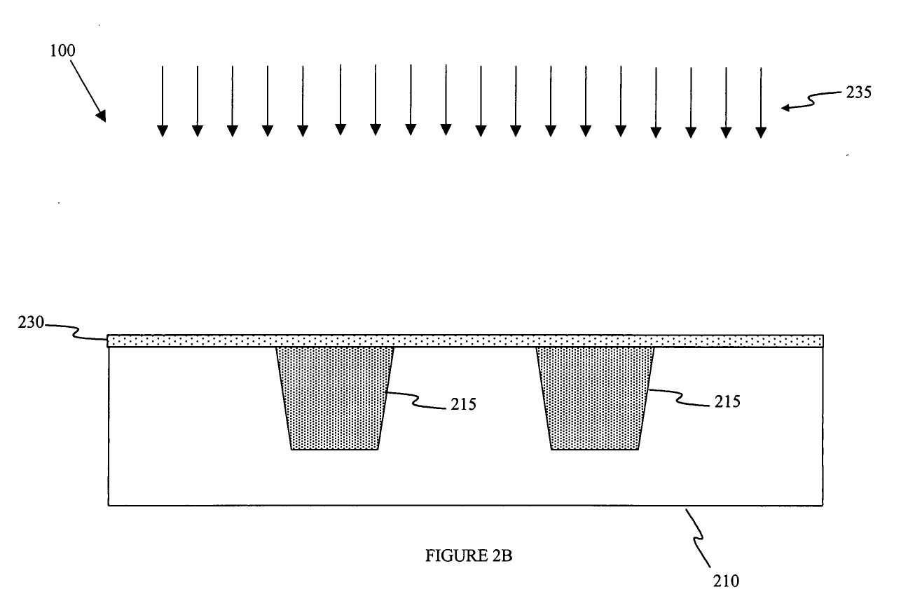

Turning now to FIG. 2A, there is illustrated a sectional view of semiconductor device 200 at an early stage of manufacture. This particular view illustrates a semiconductor substrate 210, such as a silicon substrate, having conventional isolation structures 215 formed therein. The isolation structures 215 divide the semiconductor substrate 210 into separate tub or well regions 220 and 225, which in one application may be complementary structures. However, in another embodiment, region 220 may be a low voltage core region and region 225 may be a high voltage input/out (I/O) region. At this particular stage of manufacture, a gate dielectric layer 230, such an oxide layer, has been conventionally grown over the semiconductor substrate 210. The gate dielectric layer 230 is grown to a thickness that meets the design specifications of the intended device, which may vary. The gate dielectric layer 230 may be grown in one tool and then transferred to a plasma tool (not shown). Alternatively, the gate dielectric layer 230 is grown in the plasma tool itself prior to a plasma nitridation.

Following the growth of the gate dielectric layer 230, the device is subjected to a plasma nitridation process as provided herein. FIG. 2B, illustrates the nitrogen being incorporated into the gate dielectric layer 230. The nitridation process is illustrated by the arrows designated 235.

In one embodiment, the nitridation process includes subjecting the gate dielectric layer 230 to a gas mixture including argon and nitrogen under plasma conditions. Preferably, the plasma nitridation is conducted in a microwave plasma chamber. In addition, the plasma can be conducted at higher pressures without a risk of producing unstable plasma conditions. In such embodiments, the flow rate of the argon ranges from about 1700 sccm to about 2200 sccm and a flow rate of the nitrogen ranges from about 40 sccm to about 200 sccm. In one advantageous embodiment, the flow rate of the argon is about 1950 sccm and the flow rate of the nitrogen is about 100 sccm. It should be noted that it is advantageous to keep the total flow rate of the gas mixture constant. For example, if the total flow rate of the gas mixture is specified to be 2050 sccm with argon comprising 1950 sccm of the total flow rate and nitrogen comprising 100 sccm, then if the flow rate of the nitrogen is increased to 200 sccm, the flow rate of the argon would be decreased to 1850 to keep the flow rate constant at 2050 sccm. The power of the plasma may range from about 800 watts to about 1400 watts and at temperatures ranging from about 300° C. to about 500° C.

The nitridation is also preferably conducted at high pressure. In one embodiment, the pressure preferably ranges from about 700 mT to about 1100 mT. In aspect of this embodiment, the pressure is 800 mT. These high pressure regimes are quite different from the lower pressures used in many conventional nitridation processes. While the present invention is not limited to any mechanistic theory, it is theorized that the higher pressures force the ambient or residual oxygen present in the plasma chamber closer to the semiconductor substrate, which allows the energized oxygen to more readily interact with the gate dielectric layer. The oxygen can be present as a result of residual oxygen residing in the plasma chamber, or it is believed that oxygen can come from the dielectric layer itself as the result of nitrogen atoms replacing any oxygen that might be present. In either case, the present invention does not preclude the intentional introduction of small amounts of oxygen into the plasma chamber.

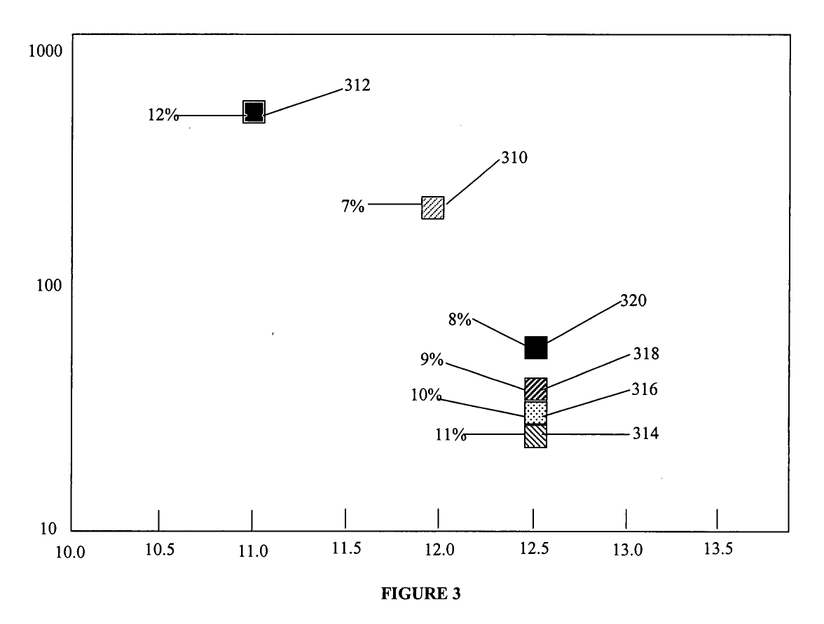

It has presently been found that adjusting the plasma process parameters can control the gate leakage of the gate dielectric layer 230. For example, the flow rate of the argon and the nitrogen may be adjusted under high pressure to provide a minimum gate leakage of the semiconductor device. FIG. 3 is a graph of gate leakage in A/cm² (current density) along the y-axis and EOT along the x-axis taken from devices 310, 312 made in accordance with prior art processes and devices 314, 316, 318 and 320 made in accordance with the present invention. The percentage numbers represents percent nitrogen in each of the respective devices. As seen from this figure, devices 310, 312, while containing a significant amount of nitrogen concentration, still had a high amount of gate leakage. Moreover, the target EOT of these devices varied substantially. In contrast, devices 314, 316, 318 and 320, while containing substantially the same amount of nitrogen concentration, exhibited substantially reduced gate leakages, all at about the same EOT values. Thus, gate leakage was reduced without sacrifice of gate performance. Additionally, different gate leakages could be achieved without sacrificing device performance as discussed above.

As seen from the embodiments represented in FIG. 3, the present invention can provide a semiconductor device wherein a concentration of nitrogen within the gate dielectric layer ranges from about 8% to about 11%, while an EOT of the gate dielectric layer of 1.25 nm is achieved. Contrary to prior processes, as shown by devices 310 and 312, the gate leakage of the gate dielectric layer can range from about 30 A/cm² to about 80 A/cm². It should specifically be noted, as shown by device 314, that a 11% nitrogen concentration can be achieved while maintaining the gate leakage around 30 to 40 A/cm² and at an EOT of about 12.5. This is in stark contrast to device 312 that shows a 12% nitrogen concentration, but at an undesirable gate leakage of about 700 to 800 A/cm² and at an EOT of about 11.0.

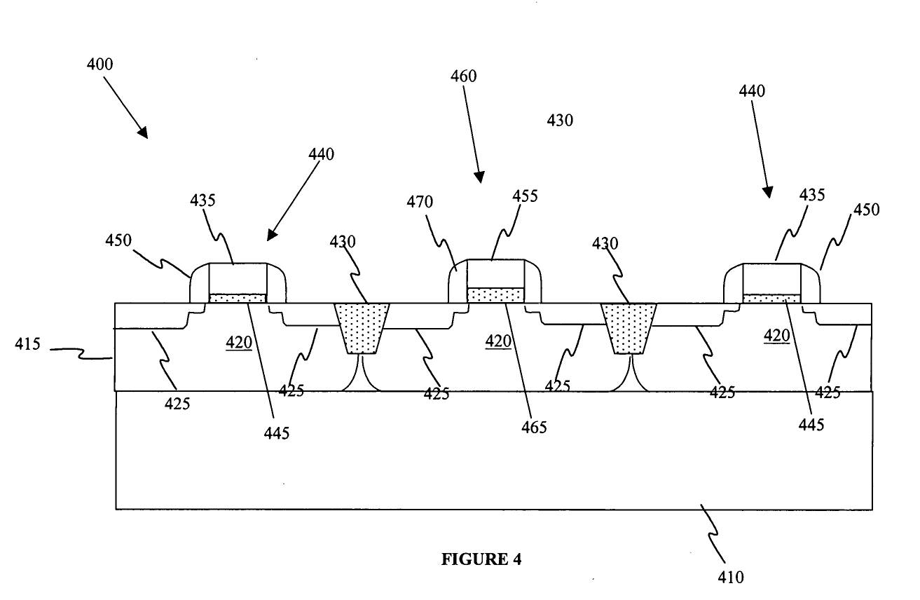

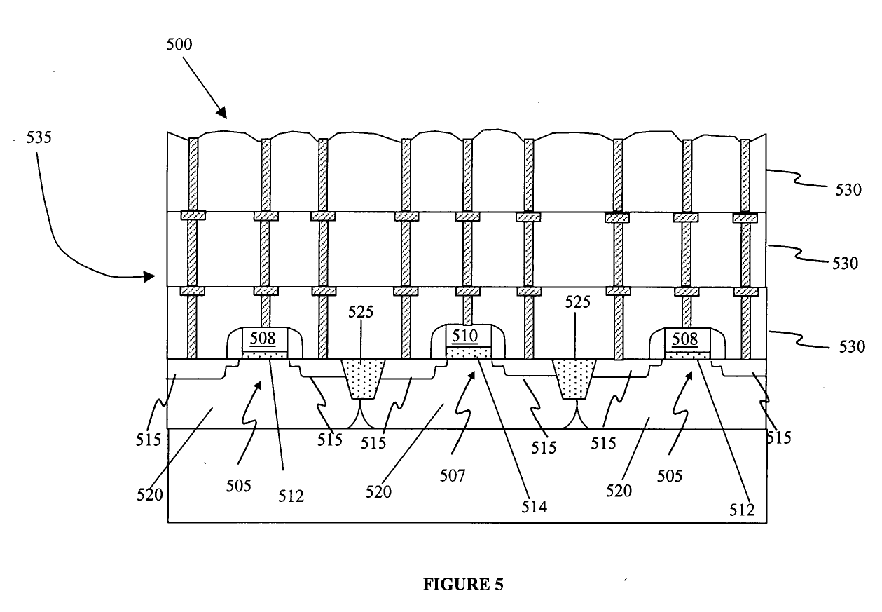

Turning now to FIG. 4, there is illustrated a sectional view of a partially completed integrated circuit device 400 after the conventional formation of transistor gates. Device 400, as mentioned above, may contain low voltage power transistor devices and high voltage, I/O transistor devices. While this is the embodiment that is illustrated, the present invention is not limited to any particular transistor configuration. In the illustrated embodiment, the device 400 includes a semiconductor substrate 410 over which is formed a tub or well layer 415 in which wells 420 and source/drain regions 425 are formed and are doped to operate at their respective designed parameters. The wells 420 are electrically isolated by conventionally formed isolation structures 430. Conventionally doped low voltage gates 435 are formed over a low voltage regions 440 and are isolated from the well 420 using a nitridated, low voltage gate dielectric layer 445 formed in accordance with the present invention. The low voltage gates 435 also include spacers 450. Shown adjacent the low voltage gates 435 for clarity, is a conventionally doped high voltage gate 455 that is formed over a HV region 460 and that is isolated from the well 420 using a nitridated, high voltage gate dielectric layer 465 formed in accordance with the present invention. The high voltage gate 455 also includes spacers 470. Also, the dual voltage device 400 may be also include metal silicide contact regions on the source/drain regions 425, which are not shown, and it can be incorporated into an integrated circuit, as shown in FIG. 5.

FIG. 5 represents a partial view of a dual voltage integrated circuit device 500 that can be fabricated in accordance with the principles of the present invention. The integrated circuit 500 includes low voltage transistors 505 and high voltage transistor 507, and each respectively includes a low voltage gate 508 and a high voltage gate 510. The gates 508 and 510 are designed to operate at their respective designed operating voltages. The low voltage gates 508 are electrically isolated by a nitridated, low voltage gate dielectric 512, and the high voltage gate 510 is electrically isolated by a nitridated, high voltage gate dielectric 514, both of which may be fabricated in accordance with the principles of the present invention.

The transistors 505 and 507 also each includes source/drains 515 formed in wells 520, which can be doped as desired. Conventional isolation structures 525 separate and electrically isolate the transistors 505 and 507 from each other. Interlevel dielectric layers 530 are located over the transistors 505 and 507 and interconnects 535 are formed therein to interconnect the various transistors 505 and 507 to form an operative integrated circuit. Given the teachings of present application, one who is skilled in the art would know how to form the operative integrated circuit as shown in FIG. 5.

Although the present invention has been described in detail, those skilled in the art should understand that they can make various changes, substitutions and alterations herein without departing from the spirit and scope of the invention in its broadest form.

What is claimed is:

1. A method for controlling the amount of gate leakage in a semiconductor device, comprising:
placing a semiconductor substrate in a plasma chamber; and
subjecting a gate dielectric layer located over said semiconductor substrate to a gas mixture including argon and nitrogen under plasma conditions, wherein a flow rate of said argon ranges from about 1700 sccm to about 2200 sccm and a flow rate of said nitrogen ranges from about 40 sccm to about 200 sccm.

2. The method as recited in claim 1 wherein said subjecting is conducted at a pressure ranging from about 700 mT to about 1100 mT.

3. The method as recited in claim 2 further including adjusting a flow rate of said argon and said nitrogen and a pressure of said plasma conditions to provide a desired gate leakage of said semiconductor device.

4. The method as recited in claim 3 wherein said desired gate leakage is achieved while maintaining a target equivalent oxide thickness.

5. The method as recited in claim 1 wherein a power of said plasma ranges from about 800 watts to about 1000 watts and a temperature of said semiconductor substrate ranges from about 300° C. to about 500° C.

6. The method as recited in claim 1 wherein subjecting is conducted in a microwave chamber and in a presence of oxygen.

7. The method as recited in claim 1 wherein a flow of said argon is about 1950 sccm.

8. The method as recited in claim 1 wherein a flow of said nitrogen is about 100 sccm.

9. The method as recited in claim 1 wherein said subjecting results in a semiconductor device wherein a concentration of nitrogen within said gate dielectric layer ranges from about 5% to about 15% and an equivalent oxide thickness of said gate dielectric layer is about 1.25 nm and a gate leakage of said gate dielectric layer ranges from about 30 A/cm² to about 80 A/cm².

10. The method as recited in claim 9 wherein said concentration of said nitrogen is about 11%.

11. A method of forming a gate dielectric in a plasma chamber, comprising:
placing a semiconductor substrate in a plasma chamber;
forming a gate dielectric layer over said semiconductor substrate;
subjecting said gate dielectric within said plasma chamber to a gas mixture including argon and nitrogen under plasma conditions, wherein a flow rate of said argon ranges from about 1700 sccm to about 2200 sccm and a flow rate of said nitrogen ranges from about 40 sccm to about 200 sccm and under high pressure.

12. The method as recited in claim 11 wherein said high pressure ranges from about 700 mT to about 11000 mT.

13. The method as recited in claim 11 further including adjusting a flow rate of said argon and said nitrogen and a pressure of said plasma conditions to provide a desired gate leakage of said semiconductor device, wherein said desired gate leakage is achieved within a targeted equivalent oxide thickness and in a presence of oxygen.

14. The method as recited in claim 11 wherein a power of said plasma ranges from about 800 watts to about 1400 watts and a temperature of said semiconductor substrate ranges from about 300° C. to about 500° C.

15. The method as recited in claim 11 wherein a flow rate of said argon is about 1950 sccm and a flow of said nitrogen is about 100 sccm.

16. The method as recited in claim 11 further including:
forming a gate layer over said gate dielectric layer;
patterning said gate layer and said gate dielectric layer into a plurality of transistor gates;
forming source/drains in well regions associated with each of said plurality of said transistor gates, said well region being located in said semiconductor substrate and between isolations regions located between said transistor gates;
forming dielectric layers over said transistor gates; and
forming interconnects in and between said dielectric layers to interconnect said transistor gates to form an operative integrated circuit.

17. A semiconductor device having a predetermined gate leakage, comprising;
a semiconductor substrate; and
a gate dielectric layer located over said semiconductor substrate, said gate dielectric layer having a concentration of nitrogen therein that ranges from about 5% to about 15% and an equivalent oxide thickness that ranges from about 1.0 nm to about 1.5 nm and wherein a gate leakage of said gate dielectric layer is less than about 100 A/cm².

18. The semiconductor device as recited in claim 17 wherein a concentration of said nitrogen is about 11% and said gate leakage ranges from about 30 A/cm² to 40 A/cm².

19. The semiconductor device as recited in claim 17 wherein said gate leakage ranges from about 30 A/cm² to about 80 A/cm².

20. The semiconductor device as recited in claim 17 wherein a concentration of said nitrogen is about 8% and said gate leakage is about 80 A/cm².
